(19) United States
(12) Patent Application Publication
(10) Pub. No.: US 2007/0033452 A1
(43) Pub. Date: Feb. 8, 2007

(54) Method and circuit arrangement for detecting errors in a data record

(76) Inventor: Steffen Marc Sonnekalb, Taufkirchen (DE)

Correspondence Address: DICKSTEIN SHAPIRO LLP, 1177 AVENUE OF THE AMERICAS 6TH AVENUE, NEW YORK, NY, 10036-2714, US

(21) Appl. No.: 11/452,582

(22) Filed: Jun. 14, 2006

(30) Foreign Application Priority Data
Jun. 14, 2005 (DE) 10 2005 027 455.2

(51) Int. Cl. G11C 29/00

(52) U.S. Cl. 714/718

(57) ABSTRACT

The method comprises providing a part-data record to be changed from a data record stored in a memory device, providing a change data record changing the part-data record to be changed and providing a check word associated with the data record. The check word is changed by a change transformation in dependence on the part-data record to be changed, the changing change data record and the check word provided. Furthermore, the method comprises performing the data record change in the memory device in dependence on the change data record and associating the changed check word with the changed data record. The changed data record is transformed into a further check word.

### FIELD OF THE INVENTION

The invention relates to a method and to a circuit arrangement for detecting errors in a data record.

### PRIOR ART

Circuit arrangements for data processing comprise memory arrangements in which the data words to be processed are made available. The actual processing of the data words takes place in an arithmetic-logic unit. The memory arrangements can be, for example, main memories for storing programs and relatively large volumes of data, or intermediate stores for providing the data for the actual data processing. In the main memory, the data remains over a relatively long period of time. In the extreme case, for example in the case of program or configuration data, the data remains for the entire life of the circuit device. The data processed by an arithmetic-logic unit is loaded into the intermediate store which allows faster access. The duration for which the data remains in the intermediate store varies. Data, for example frequently used routines, which is accessed time and time again, can remain in the intermediate store for a relatively long period of time during the data processing.

During the provision of the data, errors can occur in the data provided. For example, random errors can be caused by voltage fluctuations or by radiation, for example light. Errors can also occur when the storage device is manipulated by an attack. For this purpose, the circuit can be manipulated in its operation for example by introducing external signals, the so-called “probing”. It is also conceivable to manipulate the data by deliberate radiation, for example UV light. A hardware error in the circuit arrangement is another error source.

To ensure that the circuit arrangement is operating correctly and data processing is error-free, a check is made whether data are present unchanged.

To detect errors in the data words, so-called error codes have hitherto been used. In this arrangement, all data words to which the error detection is to be applied are first transformed into a check word. This check word is used as a reference. To detect errors, all data words are transformed again. Any differences with respect to the previous check word which may occur allow differences in the data and possibly an error to be inferred. This method presupposes that the memory content is not changed according to plan during the controlled time interval between the two transformations. The simplest form of error detection is the so-called parity bit which is appended to a data word and specifies whether the corresponding data word comprises an even number or odd number of a binary value, e.g. a logic one.

The error detection is performed, for example, immediately before it is accessed by the arithmetic-logic unit or the data are to be written into the main memory from the intermediate store.

When a data word is changed, the above described method requires the entire memory content to be read out subsequently in order to recalculate the check word which is used as comparison during the actual error detection. This reading process is time-consuming.

As an alternative, the memory area can be subdivided into a multiplicity of smaller blocks which are in each case protected with an inherent check word. In this case, too, when a data word is modified in one of the blocks, the entire block is read out in order to recalculate the check word. By subdividing the memory device into relatively small individual blocks, the expenditure of the reading-out is correspondingly reduced. However, it is associated with the disadvantage that many check words must be stored and administered, one for each block.

Both methods have in common that both in the modification of a data word in the memory device or in a block, respectively, and in the actual error detection, all data words associated with the check word must be read out in order to check the data words for errors.

### SUMMARY OF THE INVENTION

A method for changing a data record which comprises at least one data word and which is associated with a check word stored in a memory device is disclosed. The method includes providing a part-data record to be changed from the data record stored in the memory device; providing a change data record changing the part-data record to be changed; providing the check word; changing the check word by means of a change transformation in dependence on the part-data record to be changed, the changing change data record and the check word provided; carrying out the data record change in the memory device in dependence on the change data record; associating the changed check word with the changed data record; and transforming the changed data record into a transformed check word.

The circuit arrangement comprises a memory device and a transformation device and a comparison device.

The memory device has a data input, via which a changeable data record of at least one data word is supplied for storage, and with a data output via which the data record can be provided.

The transformation device is coupled to the data output of the memory device and which is constructed for providing, in dependence on the data record, a check word for storing in a check word memory or for a comparison, and which is constructed to provide, in dependence on changes on the data record and the previous stored check word, a changed check word for storing. The comparison device which is coupled to the transformation device and the check word memory and which is supplied with the stored check word and the check word provided for comparison and which is constructed for checking whether the stored check word and the check word provided for comparison have a predetermined relationship.

An advantage of an exemplary embodiment of the invention is that the method reduces the expenditure for the error detection of a data record stored in a memory. When a data word is changed, it is not necessary to read the entire data record for calculating a new check word.

The method is particularly suitable for data records with limited data volume such as are provided, for example, in intermediate stores and registers. The data record is stored divided into data words. The part-data record and/or the change data record can also be divided into data words. This check is of advantage, in particular, before the immediate use of the data in the arithmetic-logic unit. Similarly, the check, for example of data provided in the intermediate store, can take plate at regular or irregular intervals. This check is to be used for detecting errors in the data provided.

An advantage of an exemplary embodiment of the invention is that the method is flexible with regard to possible changes of the data record which comprise a replacement of at least one of the data words of the data record with another data word or a deletion of one of the data words of the data record or an addition of a further data word to the data record.

The data record is protected by an associated check word which is generated by transforming the data words of the data record. The stored data record is transformed into the check word before the check word is provided. It is appropriate if the data words are selected in such a manner that they comprise the smallest addressable area of a memory unit, for example one byte. As an alternative, the data words can also consist of a block comprising a number of addressable units. The transformation can advantageously additionally depend on information words, one information word being allocated to each data word. The information words increase the protection when the data words comprise only a few bits since the transformation has more input parameters.

As a rule, the information word depends on the type of provision of the data word, for example it involves address information about the corresponding data word. The additional information prevents similar errors from not being detected in different data words because they possibly cancel during the transformation.

The transformation advantageously comprises a function which is applied to each data word of the data record in order to allocate to this data word a so-called hash data word. This process is also called “hashing”. The corresponding function is also called “hash function”. The function can advantageously also depend on the data word and the information word allocated to the data word in order to increase the protection of the method. The hash data words of a data record are combined in order to generate the check word. This combining can advantageously be an exclusive-OR combination which is simple to implement.

The check word is changed when the data record is changed. The function is applied to the data word to be deleted or to be added or to be replaced and to the replacing data word. Following this, the hash data words thus generated and the previous check word are combined to form a new check word. The changed check word is stored. It can be changed again. It is not required to read out all data words of the data record again when a data word is changed.

Finally, the stored check word and another check word which is generated by the transformation of the changed data record are compared and an alarm function is triggered when no predetermined relationship exists. The simplest relationship, which is also simple to check, is the identity of the two check words.

The circuit arrangement comprises a memory device for the data record which can be changed in such a way that a part of the data record can be added and/or a part of the data record can be deleted and/or a part of the data record can be replaced. The corresponding parts of the data record can comprise one or more data words.

To improve the error detection, a corresponding information word can be allocated to each data word. The information word advantageously depends on address information of the data word. These are, for example, the memory or register addresses, the position in the intermediate store or the so-called tag address of the data word. The tag address designates an original memory address of the data word even if the latter is provided in the meantime in another memory, for example an intermediate store.

Furthermore, the transformation device is arranged in such a manner that a function can be applied to each data word in order to allocate to each data word a corresponding hash data word. This function can be applied to current data words of the instantaneous data record and data words to be added and replacing data words. The hash data word depends either on the data word or additionally on the associated information word to increase security.

The check word is generated by combining the hash data words of the data record by means of a combining device. This combining device is advantageously an exclusive-OR combination which is associated with simple implementation.

For a simple and low-expenditure implementation, the function block and the combining devices are used for performing both changes in the check word in dependence on changes of the data record and the transformation of the data record.

In this process, a corresponding hash data word which is combined with the previous check word is allocated to the data word to be deleted. A similar procedure is adopted for a data word to be added.

When a data word is changed, the corresponding hash data word is allocated both to the replacing data word and to the data word to be replaced and is combined with the previous check word.

The changing of the check word is not associated with a repeated read-out of all the data words within the data record.

For the error detection, a data word is generated by the transformation device from the current data record, which may have been changed several times, and supplied to the comparison device together with the previous stored check word.

The comparison device is constructed in a simple form in such a manner that it can check the identity of the check words supplied.

### BRIEF DESCRIPTION OF THE DRAWINGS

In the text which follows, the invention will be explained by means of exemplary embodiments, referring to the drawing.

FIG. 1 shows the transformation of a data record with data words into a first check word by means of a block diagram.

FIG. 2 shows a block diagram of the transformation.

FIG. 3 shows a change of the first check word.

FIG. 4 shows the change of the first check word in detail.

FIG. 5 shows the transformation of the data record into a second check word and a subsequent comparison.

FIG. 6 shows the transformation of a data record with data words and information words into the first check word.

FIG. 7 shows the change of the first check word.

FIG. 8 shows the transformation of the data record into the second check word and the subsequent comparison.

FIG. 9 shows a circuit arrangement for error detection.

FIG. 10 shows a transformation device of the circuit arrangement.

### DETAILED DESCRIPTION OF THE DRAWING

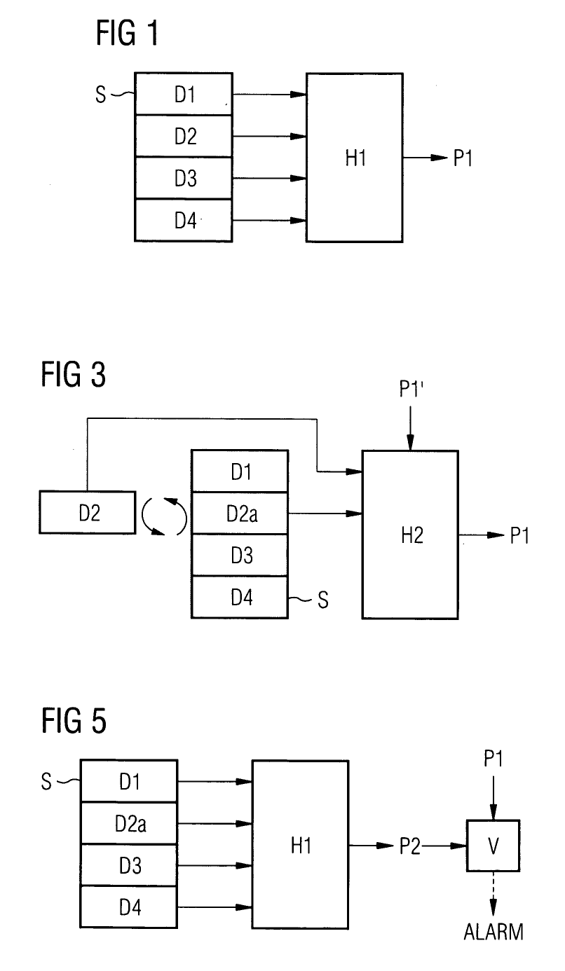

FIG. 1 shows a block diagram with a data record S which, for example, comprises a first to fourth data word D1, D2, D3, D4. The data words D1, D2, D3, D4 of the data record S are transformed into a first check word P1 by a transformation H1.

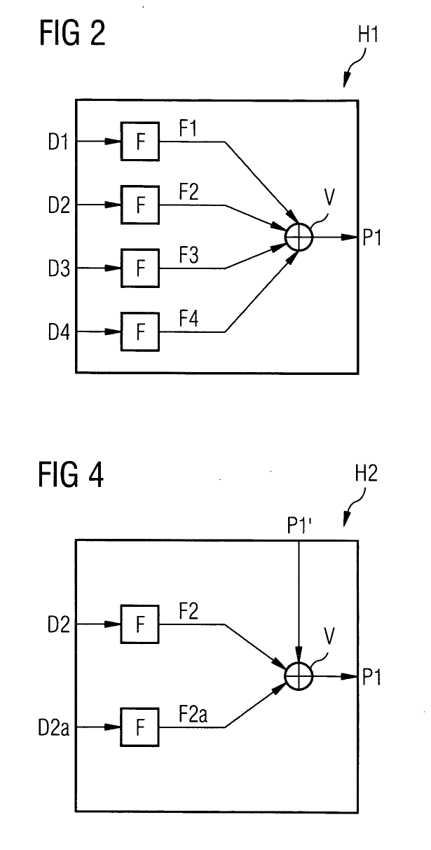

FIG. 2 shows a possible transformation H1. Initially, each of the data words D1, D2, D3, D4 is mapped onto a hash data word F1, F2, F3, F4 by a function F. The hash data words F1, F2, F3, F4 of the data record S are changed into the first check word P1 by a suitable combination V. A bit-wise exclusive-OR combination is shown as combination V.

The function for “hashing” is distinguished by changing a long input, namely the data word, into a short output. Advantageously, similar inputs lead to completely different outputs. In the choice of a suitable function, the efficiency, that is to say the fast calculating capability, must not be neglected in order to keep the expenditure of the error detection method as low as possible.

It is also conceivable to perform the transformation H1 when the function F maps the data words D1, D2, D3, D4 unchanged as hash data words F1, F2, F3, F4. To illustrate, this means omitting the blocks with the function F in FIG. 2.

FIG. 3 shows how the first check word P1 is changed when the data record S is changed.

The exemplary change of the data record S indicated in FIG. 3 consists in replacing the second data word D2 by a new second data word D2a. The first check word P1 is updated in dependence on the change of the data record S. This updating or changing of the first check word P1 depends on a change transformation H2 which, in turn, is dependent on the previous first check word which is here designated as P1′ for distinction, and the data words D2 and D2a on which the change is dependent.

The unchanged data words D1, D3, D4 are not relevant for the change transformation H2 for determining the changed first check word P1.

The change transformation H2 has the effect that initially a component of the first check word P1 originating from D2 is removed and is replaced by a component originating from the new second data word D2a.

FIG. 4 shows the steps of the change transformation H2 when the transformation H1 shown in FIG. 2 is used as a basis for determining the first check word P1.

The previous second data word D2 is changed into the second hash data word F2 by the function F. The new second data word D2a, too, is changed into the corresponding new second hash data word F2a by the function F. The two hash data words F2 and F2a are combined with the previous first check word P1′ by the combination V. The combination V is again a bit-wise exclusive-OR combination, the properties of which include that a double exclusive-OR combination of a word with another word does not change the other word. For this reason, the component of the second hash data word F2 in the first check word P1 is eliminated by the exclusive-OR combination of the second hash data word F2, belonging to the second data word D2 to be replaced, with the first check word P1. The eliminated component of the second hash data word F2 originates from the transformation H1 in FIG. 2. In this manner, the component of the second data word D2 is eliminated from the first check word P1.

To receive information about the new second data word D2a in the first check word P1, the new second data word D2a is changed into the new second hash data word F2a by means of the function F and is again combined with the previous check word P1′ by means of the bit-wise exclusive-OR combination V. The previous and the new second data word D2, D2a can be combined with the previous first check word P1′ in one step as is shown in FIG. 4.

As an alternative, it is also conceivable first to combine the second data word D2 to be replaced with the previous first check word P1′ and then to combine the new second data word D2a to be replaced with the result. Naturally, this order can also be exchanged.

The method described above functions similarly when a data word is added to the data record S. In this case, the change transformation H2 only has a combination of two elements, namely the previous first check word P1′ and the hash data word of the data word to be added which is combined with the previous first check word P1′ via a function F to become the updated first check word P1. In this manner, the data word to be added is taken into consideration in the first check word P1.

When a data word is deleted from the data record S, the procedure is similar only instead of the hash data word of the data word to be replaced, the hash data word of the data word to be deleted is combined with the previous first check word P1′. In this manner, the component of the data word to be deleted is eliminated in the first check word P1.

Naturally, the first check word P1 can also be changed several times in one or more of the ways described above.

FIG. 5 illustrates the actual error detection of the method. The current, changed data record S which comprises the data words D1, D2, D3, D4 is changed into a second check word D2 by means of the transformation H1. The transformation H1 corresponds to the transformation H1 of FIG. 1 by means of which the first check word P1 is also generated before the change.

In a comparison, the first check word P1 and the second check word P2 are checked as to whether they are in a given relationship. If no errors have occurred during the provision and changing of the data record, the first and second check word P1 and P2 are in the given relationship. If this is not the case, an alarm function ALARM can be triggered.

As a rule, the given comparison is a comparison as to whether the first check word P1 and the second check word P2 are identical. However, it is also conceivable for there to be another relationship. In this case, the transformations H1 in FIGS. 1 and 5 would differ and, with the same input data, would apply different first and second check words P1, P2, the relationship of which, however, fulfills the relationship to be checked in the comparison V in the case of an error-free data record S.

If on the of the data words, either one of the original ones or one of the changed ones D1, D2, D3, D4 has been changed, for example due to an attack, after its information has been taken into consideration by the transformation H1 or the change transformation H2 in the first check word P1, this error-related change is detected by the step shown in FIG. 5. In this case, the transformation H1 supplies a second check word P2 which differs from the first check word P1 and by means of which a data manipulation or a random error can be inferred.

Naturally, the error detection also functions when the data record S is not changed. In this case, the step shown in FIG. 3 is not performed and the first check word P1 is not changed.

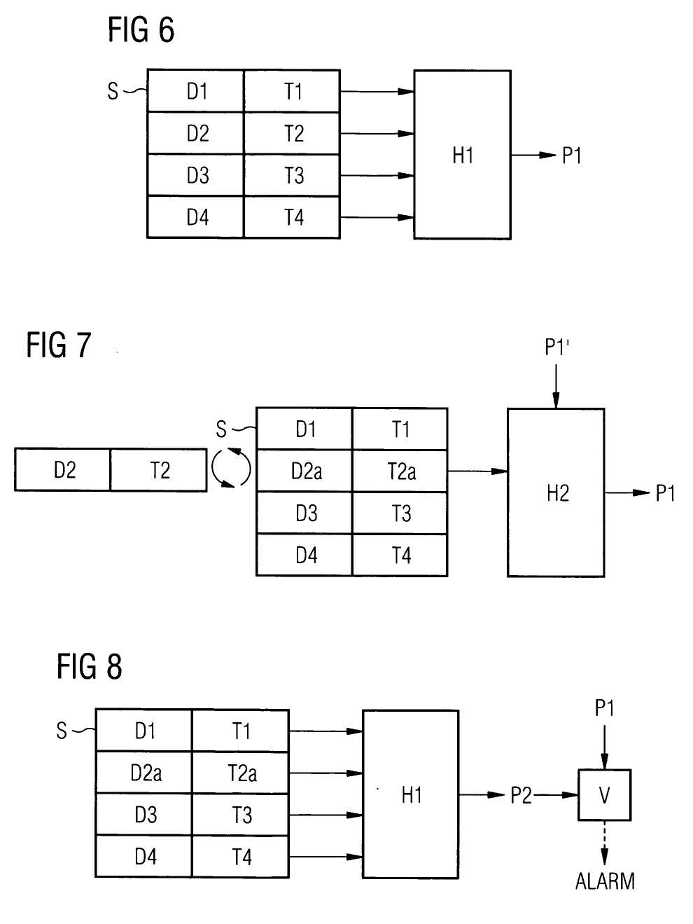

FIG. 6 differs from FIG. 1 in that a data record S is provided not only with data words D1, D2, D3, D4 but also with information words T1, T2, T3, T4 in each case allocated to the data words and changed into the first check word P1 by means of the transformation H1. The information words are advantageously information dependent on the data content of the data words D1, D2, D3, D4 in order to increase the range of protection.

In this case, too, the transformation H1 is configured like the one shown in FIG. 2. The function F here only differs in that the hash data word is dependent both on the data word and on the information word allocated to the data word. In this manner, different hash data words are allocated to the same data words which increases the protection. Since, as a rule, the hash data word is smaller than the associated data word, a number of different data words can generate the same hash data word. This can be avoided by sufficiently large input words, in this case the data word and the information word, so that overlaps become improbable. This applies especially if the data words comprise the smallest possible adjustable unit, for example one byte.

For the information word, information about the storage of the corresponding data word is used, as a rule. This can be the corresponding address in memory or the corresponding register address or, if the word is provided in an intermediate store in the meantime, the corresponding intermediate-store address. As an alternative, a so-called tag address is also conceivable as information word. The tag address specifies the place at which the data word has originally been stored, even if it is provided in another memory or intermediate store, respectively, in the meantime.

FIGS. 7 and 8 also differ from FIGS. 3 and 5, respectively, in that the change transformation H2 or the transformation H1 are performed on the basis of a data record S with data words D1, D2, D2a, D3, D4 and the information words T1, T2, T2a, T3, T4 in each case allocated to the data words. In this case, too the changes only relate to the function F in the above-mentioned manner.

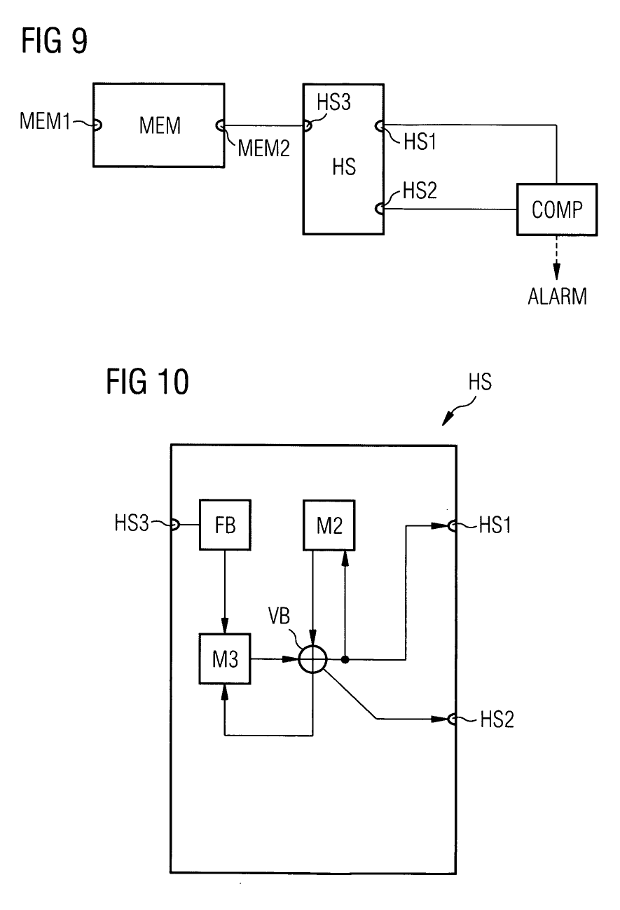

FIG. 9 shows a circuit arrangement with a memory device MEM with an input MEM1 for applying data words. The memory MEM is coupled to a transformation device HS. The transformation device HS is coupled to a comparison device COMP via a first output HS1 and a second output HS2.

The memory MEM can be both a main memory and an intermediate store or a register.

The memory device MEM is arranged for providing a data record S with data words. This data record S is changeable. The data words can be replaced, added or deleted.

The transformation device HS performs the transformation H1, already described, and the change transformation H2 for the data record S provided in the memory MEM.

The transformation device HS is arranged for providing the first check word P1 via the output HS1 and the second check word P2 via the output HS2 for the comparison device COMP. The comparison device COMP checks whether the first check word and the second check word have a given relationship and outputs an alarm signal ALARM as necessary. The statements made in the description of the method apply to the given relationship.

With regard to the alarm signal, the responses of the circuit arrangement to this can be manifold. Apart from the mere indication of a detected error, it is also conceivable to shut down the circuit arrangement or to perform a so-called reset, that is to say shutting down followed by a start-up into a defined initial state.

The data record S in the memory MEM only needs to be read out as a whole, and supplied to the transformation device HS, for the initial generation of the first check word P1. When a data word is changed, the data word to be replaced is read out into the transformation device HS and subjected to the change transformation H2. The replacing data word is then conveyed to the transformation device, subjected to the change transformation for updating the first check word and stored in the memory so that the data record is changed.

As an alternative, the data words can also be applied directly to the transformation device HS, possibly via a further input. In this case, the data would be applied in parallel to the memory MEM and the transformation device HS. This would allow a read-out for providing the data for the transformation device HS to be bypassed. It is also conceivable that the data at the input MEM1 of the memory MEM are also picked up and looped through to the output MEM2 in order to provide the data undelayed for the transformation device HS. In these cases, the data record, possibly changed, is essentially read out of the memory MEM for generating the second check word.

FIG. 10 shows the essential blocks of the transformation device HS. For providing the first check word, it comprises a function block FB by means of which the data words present at the input HS3, or the data words plus associated information words, are changed into corresponding hash data words.

Since a number of hash data words are combined with one another in the initial generation of the first check word P1, in the generation of the second check word P2 and the replacement of a data word, a register M3 is provided between the function block FB and the combining device VB in order to temporarily store a number of hash data words and supply them to the combining device VB for combining. To save expenditure, the function block FB is provided only once. Naturally, a parallel arrangement of a number of function blocks FB similar to the block diagram in FIG. 2 is also conceivable.

The combining V is effected via a combining device VB by means of which the advantageous exclusive-OR combination is implemented. The exclusive-OR combination of a number of data words does not need to take place in parallel but can also be implemented by progressively combining an intermediate result with a further data word which reduces the hardware expenditure.

Furthermore, a register M2 which provides the respective current first check word P1 is provided in the transformation device HS. This register is both connected at the input end to the combining device VB in order to provide the previous first check word P1 and is also connected at the output end to the combining device VB in order to store the updated first check word P1 after the combining. The first check word is output via a first output HS1. The second check word is output via the second output HS2.

The register M2 is used as check word store. Alternative embodiments of the check word store are conceivable, for example as separate block, as block coupled to one of the devices, as external store, as area of the memory device reserved for this purpose or flexibly assigned, or another memory of the circuit arrangement.

The method described above makes it possible to quickly check the data words of the data record provided. Checking is available, for example, when processor calculating times are not used in other ways. For this purpose, it is of advantage if the data record S to be checked is not too large so that a quick check is made possible. For large stores or registers, it is conceivable, therefore, to subdivide these into one or more data records S and in each case to check only the data record S of one of the store or register parts in idle times. A data record having, for example, eight words of 64 bytes length in each case has been found to be manageable with regard to the expenditure.

Naturally, it is also conceivable to utilize the error detection not only during idle processor calculating times but also to allow it to run in parallel in the background or to perform at particular times which, for example, are predetermined by the user or are permanently anchored in the system.

The method described is also suitable for processing data in blocks, for example preceding block-by-block decoding. In this case, the content of the data record changes block by block in order to process large volumes of data. In this case, the error detection can run in parallel with the processing of a block in which, for example, the first check word is changed whilst the preceding block is processed. As a result, a time delay only arises at the beginning of the block-by-block data processing.

What is claimed is:

1. A method for changing a data record stored in a memory device, which comprises at least one data word and which is associated with a control word, the method comprising:
providing a part-data record to be changed from the data record stored in the memory device;
providing a change data record changing the part-data record to be changed;
providing the control word;
changing the control word by a change transformation based on the part-data record to be changed, the change data record and the control word;
performing the data record change in the memory device based on the change data record;
associating the changed check word with the changed data record; and
transforming the changed data record into a transformed check word.

2. The method as claimed in claim 1, wherein performing the data record change further comprises:
replacing the part-data record with at least one data word to be replaced from the data record by the change data record with at least one replacing data word; or
adding the change data record, the change data record comprising at least one data word to be added to the data record and the part-data record comprising no data word, or
deleting the part-data record, the part-data record comprising at least one data word, to be deleted, of the data record and the change data record comprising no data word.

3. The method as claimed in claim 1, wherein an information word is allocated to each data word, which is dependent on a location of the data word and wherein the transforming of the data record depends on the data words of the data record and their associated information words.

4. The method as claimed in claim 1, wherein transforming the changed data record further comprises a combining of the data words of the data record.

5. The method as claimed in claim 2, wherein, when a data word is replaced, the change transformation comprises combining the data word to be replaced and the replacing data word with the previous check word or when adding or when deleting, the change transformation comprises a combining of the data word to be added or the data word to be deleted, respectively, with the previous check word.

6. The method as claimed in claim 1, wherein the transforming and the change transformation comprises a function by means of which a hash data word is allocated to the data word or to the data word and an associated information word.

7. The method as claimed in claim 6, wherein transforming the changed data record further comprises combining the hash data words of the data record with the check word.

8. The method as claimed in claim 6, wherein, when replacing a data word, the change transformation comprises combining the hash data word of the data word to be replaced and the hash data word of the replacing data word with the previous check word or when adding or when deleting, the change transformation comprises combining the hash data word of the data word to be added or of the hash data word of the data word to be deleted, respectively, with the previous check word.

9. A method for changing a data record stored in a memory device, which comprises at least one data word and with which a check word is associated, the method comprising:
providing a part-data record to be changed from the data record stored in the memory device;
providing a change data record changing the part-data record to be changed,
providing the check word;
changing the check word by means of a change transformation based on the part-data record to be changed, the change data record and the control word provided that,
during a replacing, a hash data word is allocated to the data words of the part-data record to be replaced and a hash data word is allocated to the data words of the replacing change data record and the hash data words are combined with the check word, or
during an addition, wherein the part-data record does not comprise a data word, a hash data word is allocated to the data words of the change data record to be added and the hash data words are combined with the check word, or
during a deletion, wherein the change data record does not comprise a data word, a hash data word is allocated to the data words of the part-data record to be deleted and the hash data words are combined with the check word,
performing the data record change in the memory device based on the change data record;
associating the changed check word with the changed data record; and
transforming the changed data record into a transformed check word by allocating in each case to the data words of the data record a hash data word which are combined with one another.

10. The method as claimed in claim 9, wherein the combining is a bit-wise exclusive-OR combination.

11. The method as claimed in claim 9, wherein the associated check word with the transformed check word are checked to see whether a predetermined relationship exists between the associated check word and the transformed check word.

12. The method as claimed in claim 11, wherein the predetermined relationship is the identity of the associated check word and of the transformed check word.

13. A circuit arrangement comprising:
a memory device with a data input via which a changeable data record of at least one data word is supplied for storage, and with a data output via which the changeable data record can be provided;
a transformation device coupled to the data output of the memory device and which is arranged for providing, based on the data record, a check word for storage in a check word store or for a comparison and which is arranged for providing, based on changes in the data record and the previous stored check word, a changed check word for storage; and
a comparison device coupled to the transformation device and the check word store and which is supplied with the stored check word and the check word provided for comparison, and which is arranged for checking whether the stored check word and the check word provided for comparison have a predetermined relationship.

14. The circuit arrangement as claimed in claim 13, wherein the transformation device further comprises a data input via which the changeable data record and/or changes in the data record are supplied.

15. The circuit arrangement as claimed in claim 13, wherein the memory arrangement is arranged in such a manner that at least one data word to be replaced in the data record can be replaced by a replacing data word or that at least one data word to be deleted in the data record can be deleted or that a data word to be added can be added to the data record.

16. The circuit arrangement as claimed in claim 13, wherein an information word which comprises address information of the data word can be allocated to the data word.

17. The circuit arrangement as claimed in claim 13, wherein the transformation device further comprises a function block which is constructed for allocating a hash data word at least to the data word.

18. The circuit arrangement as claimed in claim 13, wherein the transformation device further comprises a combining device which generates the stored check word or the check word provided for the comparison from the data words or from the data words and their associated information words.

19. The circuit arrangement as claimed in claim 17, wherein the combining device is arranged for generating from the hash data words the check word for storage or the check word provided for comparison.

20. A circuit arrangement comprising:
a memory device with a data input via which a changeable data record of at least one data word is supplied for storage, and with a data output via which the changeable data record can be provided;
a transformation device coupled to the data output of the memory device, the transformation device comprises a combining device, the transformation device is arranged for providing from the data words of the data record a check word which is generated by the combining device for storing in a check word store or for a comparison, and the transformation device is further arranged for providing from changes in the data record and the previous stored check word a changed check word which is generated by the combining device for storing; and
a comparison device coupled to the transformation device and the check word store and which is supplied with the stored check word and the check word provided for comparison, and which is arranged for checking whether the stored check word and the check word provided for comparison have a predetermined relationship.

21. The circuit arrangement as claimed in claim 20, wherein the combining device generates the check word for storing from the previous stored check word and from the data word to be replaced and the replacing data word or from the data word to be replaced and an associated information word and the replacing data word and an associated information word.

22. The circuit arrangement as claimed in claim 20, wherein the transformation device further comprises a function block for allocating a hash data word to the data word or to the data word and an associated information word.

23. The circuit arrangement as claimed in claim 20, wherein
for replacing, the combining device generates the check word for storing from the previous stored check word and the hash data words of the data word to be replaced and the replacing data word, or
for deleting or adding, the combining device generates the check word for storing from the previous stored check word and from the hash data word of the data word to be deleted or from the hash data word of the data word to be added, respectively.

24. The circuit arrangement as claimed in claim 20, wherein the combining device comprises a bitwise exclusive-OR combination.

25. The circuit arrangement as claimed in claim 20, wherein the comparison device is constructed for checking the identity of the stored check word and of the check word provided for comparison.

26. The circuit arrangement as claimed in claim 16, wherein the transformation device comprises a function block which is constructed for allocating a hash data word at least to the data word.

27. The circuit arrangement as claimed in claim 16, wherein the transformation device comprises a combining device which generates the stored check word or the check word provided for the comparison from the data words or from the data words and their associated information words.
